(19) United States
(12) Patent Application Publication
(10) Pub. No.: US 2025/0056107 A1
(43) Pub. Date: Feb. 13, 2025

(54) CAMERA MODULE AND OPTICAL DEVICE COMPRISING SAME

(71) Applicant: LG INNOTEK CO., LTD., Seoul (KR)

(72) Inventor: Sang Yeon HAN, Seoul (KR)

(21) Appl. No.: 18/692,958

(22) PCT Filed: Sep. 16, 2022
(86) PCT No.: PCT/KR2022/013864

§ 371 Date: Oct. 8, 2024

(30) Foreign Application Priority Data
Sep. 16, 2021 (KR) 10-2021-0124383

(51) Int. Cl. H04N 23/52; H04N 23/54; H04N 23/55; H05K 1/02; H05K 1/11; H05K 1/18

(52) U.S. Cl. CPC H04N 23/52; H04N 23/54; H04N 23/55; H05K 1/0271; H05K 1/114; H05K 1/183

(57) ABSTRACT

A camera module according to an embodiment includes a reinforcing plate; an image sensor disposed on the reinforcing plate; a driver device disposed on the reinforcing plate and spaced apart from the image sensor in a horizontal direction; and a circuit board disposed on the reinforcing plate and including a cavity overlapping the image sensor and the driver device in a vertical direction, wherein the circuit board includes a first pad and a second pad, wherein the image sensor is connected to the first pad in the cavity, and wherein the driver device is connected to the second pad in the cavity.

### TECHNICAL FIELD

An embodiment relates to a camera module and an optical device including the same.

### BACKGROUND ART

Recently, an ultra-small camera module is being developed, and the ultra-small camera module is widely used in a small electronic product such as a smartphone, a laptop, and a game console.

That is, most mobile electronic devices, including smartphones, are equipped with a camera device for obtaining an image from an object, and the mobile electronic devices are gradually becoming smaller for easy portability.

Such a camera device generally may include a lens through which light is incident, an image sensor that captures light incident through the lens, and a plurality of components for transmitting and receiving electrical signals for images obtained from the image sensor to an electronic device equipped with a camera device. In addition, these image sensors and components are generally mounted on a printed circuit board and connected to an external electronic device.

On the other hand, the conventional camera device uses a printed circuit board so that the image sensor is located at a high position. However, when the image sensor is directly mounted on the printed circuit board as described above, there is a problem in that heat generated from the image sensor is not emitted, and thus there is a reliability problem due to heat generation. Recently, the pixels or size of image sensors are increasing for high resolution, and thus the heat problem of the image sensor further affects the performance of the camera device.

In addition, a printed circuit board in a conventional camera device is disposed on a reinforcing plate such as a stiffener, and the image sensor is disposed on the reinforcing plate, and then is connected to the printed circuit board through wire bonding. In this case, a cavity exposing a surface of the reinforcing plate is formed in the printed circuit board. In this case, when the cavity type printed circuit board and the reinforcing plate are used, the heat dissipation problem can be solved while increasing the height of the image sensor. In such a camera device, an epoxy for bonding an image sensor is applied on the reinforcing plate, and the image sensor is disposed on the applied epoxy. However, the camera device as described above has a problem in that warpage occurs due to a difference between a coefficient of thermal expansion of the image sensor, a coefficient of thermal expansion of the printed circuit board, and a coefficient of thermal expansion of the epoxy. For example, thermal curing proceeds in a state in which an image sensor is disposed on the epoxy. In this case, when the thermal curing proceeds, the configuration including the reinforcing plate, the epoxy and the image sensor is heat-expanded and then contracted, and accordingly, there is a problem that the warpage phenomenon occurs severely in a shape like ‘∩’. In addition, when the warpage phenomenon of the image sensor occurs, there is a problem in that the resolution performance of the camera device is deteriorated, and thus the yield of the camera device is decreased.

Additionally, a conventional camera device has a structure that includes a reinforcing plate, and because of this, there is a problem in that an overall height of the camera device increases by a thickness of the reinforcing plate.

Additionally, a conventional camera device includes a driver device that controls the overall operation of the actuator. At this time, the driver device is placed on the circuit board and can control the overall operation of the actuator accordingly. Additionally, the conventional camera device does not include a heat dissipation structure that dissipates heat generated from the driver device.

Additionally, the conventional camera device has a problem in that camera performance is degraded due to heat generated from the driver device. For example, the heat generated from the driver device is transferred to a lens placed on an upper side of the driver device. As a result, the performance of the lens deteriorates, and the resolution of the camera device deteriorates due to the deterioration of the lens performance.

Accordingly, there is a need for a camera device with a structure that can efficiently dissipate heat generated from the image sensor and driver device while minimizing the occurrence of warpage of the image sensor and reducing a height of the camera device.

### DISCLOSURE

### Technical Problem

An embodiment provides a slim camera module and an optical device including the same.

Additionally, the embodiment provides a camera module and an optical device including the same that can improve the heat dissipation characteristics of an image sensor by increasing a thickness of a reinforcing plate without increasing a thickness of the camera module.

Additionally, the embodiment provides a circuit board and an optical device including the same that can improve the heat dissipation characteristics of a driver device and an optical device including the same.

Additionally, the embodiment provides a camera module and an optical device including the same that can improve the performance of the lens by preventing heat generated from the driver device from being transferred to the lens.

In addition, the embodiment provides a camera module and an optical device including the same that can easily check an operating state of a passive device and prevent an increase in a thickness of the camera module due to the passive device.

In addition, the embodiment provides a camera module and an optical device including the same that can improve the operation reliability of a lens driving part while reducing the thickness of the camera module by placing a passive device at a position overlapping with a lens driving part in an optical axis direction.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A camera module according to an embodiment comprises a reinforcing plate; an image sensor disposed on the reinforcing plate; a driver device disposed on the reinforcing plate and spaced apart from the image sensor in a horizontal direction; and a circuit board disposed on the reinforcing plate and including a cavity overlapping the image sensor and the driver device in a vertical direction, wherein the circuit board includes a first pad and a second pad, the image sensor is connected to the first pad in the cavity, and the driver device is connected to the second pad in the cavity.

In addition, the cavity of the circuit board includes a first cavity overlapping the image sensor in the vertical direction; and a second cavity spaced apart from the first cavity in the horizontal direction and overlapping the driver device in the vertical direction.

In addition, the reinforcing plate includes a first region overlapping the circuit board in the vertical direction, a second region overlapping the first cavity in the vertical direction, and a third region overlapping the second cavity in the vertical direction, wherein a first adhesive member is disposed between the second region of the reinforcing plate and the image sensor; and wherein a second adhesive member is disposed between the third region of the reinforcing plate and the driver device.

In addition, the circuit board includes a first substrate layer disposed on the reinforcing plate, and a second substrate layer disposed on the first substrate layer, wherein at least one of the first cavity and the second cavity is provided in the first substrate layer and the second substrate layer with a step in the horizontal direction.

In addition, the first cavity includes a first-first through hole passing through the first substrate layer, and a first-second through hole passing through the second substrate layer and having a width greater than a width of the first-first through hole, and wherein the first pad is disposed on an upper surface of the first substrate layer vertically overlapping the first-second through hole.

In addition, the camera module further comprises a first connection member connecting a terminal of the image sensor and the first pad, wherein the first connection member is disposed in the first-second through hole, and wherein an uppermost end of the first connection member is located lower than an uppermost end of the second substrate layer.

In addition, the second cavity includes a second-first through hole passing through the first substrate layer, and a second-second through hole passing through the second substrate layer and having a width greater than a width of the second-first through hole, and wherein the second pad is disposed on an upper surface of the first substrate layer vertically overlapping the second-second through hole.

In addition, the camera module further comprises a second connection member connecting a terminal of the driver device and the second pad, and wherein the second connection member is disposed in the second-second through hole, and wherein an uppermost end of the second connection member is located lower than an uppermost end of the second substrate layer.

In addition, the image sensor includes an overlapping region disposed in the first-second through hole of the first cavity and vertically overlapping the first pad.

In addition, the reinforcing plate includes a first plate portion disposed on a lower surface of the first substrate layer, and a second plate portion protruding from the first plate portion and including at least a portion disposed in the first-first through hole of the first cavity, wherein the image sensor is disposed on the second plate portion in the first-second through hole, and wherein a bonding part is disposed between the terminal of the image sensor and the first pad.

In addition, the camera module includes a filter disposed on the circuit board, and the lower surface of the filter directly contacts the upper surface of the second substrate layer of the circuit board.

In addition, the camera module further comprises a filter attached to the image sensor and wherein the filter includes at least a portion of the filter disposed within the first-second through hole of the first cavity.

In addition, the camera module further comprises a passive device disposed on the circuit board, wherein the first substrate layer includes a third through hole that is horizontally spaced apart from the first and second cavities and vertically overlaps the second substrate layer, and the passive device is disposed in the third through hole.

In addition, the camera module further comprises a molding layer for molding the passive device in the third through hole, and the molding layer contacts the reinforcing plate.

### Effects of the Invention

The camera module according to the embodiment comprises a circuit board including a first cavity that vertically overlapping an image sensor and composed of a first substrate layer and a second substrate layer. Additionally, the first cavity includes a first-first through hole formed in the first substrate layer. Additionally, the first cavity includes a first-second through hole formed in the second substrate layer and vertically overlapping the first-first through hole. At this time, the first-second through hole has a width greater than the width of the first-first through hole. Accordingly, the first cavity including the first-first through hole and the first-second through hole have a step. Also, in the embodiment, an image sensor is disposed in the first-first through hole, and a connection member connected to the image sensor is disposed in the first-second through hole. Accordingly, the embodiment can prevent a height of the camera module from increasing due to the height of the connection member in a structure in which an image sensor is mounted using a wire bonding method, and accordingly, an overall height of the camera module can be reduced. Furthermore, the embodiment does not need to consider a height of the connection member to place the filter, and accordingly, the filter can be placed directly on the circuit board. Accordingly, the embodiment may remove the holder for placing the filter. And, in the embodiment, the holder can be removed, thereby reducing the overall height of the camera module by the height of the holder.

Accordingly, in the camera module of the embodiment, a first height H1 corresponding to a Flange Back Length (FBL) or a second height H2 corresponding to a Total Track Length (TTL) can be reduced compared to the comparative example. For example, in a camera module of the comparative example, the first height h1 corresponding to FBL (Flange Back Length) and the second height h2 corresponding to TTL (Total Track Length) are is determined by reflecting the height of the connection member or the height of the holder on which the filter is mounted, and accordingly, the height of the connection member and the height of the holder increase. In contrast, the embodiment allows the connection member to be disposed in the cavity of the circuit board, and allows the filter to have a structure that is directly mounted on the circuit board. Accordingly, the first height H1 corresponding to the Flange Back Length (FBL) and the second height H2 corresponding to the Total Track Length (TTL) may be reduced compared to the comparative example.

Additionally, the camera module in the embodiment includes a reinforcing plate. At this time, the reinforcing plate includes a first plate portion disposed on the lower surface of the first substrate layer, and a second plate portion protruding from the first plate portion and disposed in the first-first through hole of the first cavity. Additionally, the image sensor may be connected to the first pad using a flip chip bonding method while being disposed on the second plate portion. Accordingly, in the embodiment, a thickness of the reinforcing plate can be increased without increasing the height of the camera module, and the heat dissipation characteristics can be improved accordingly.

In addition, the circuit board in the embodiment includes a second cavity. The second cavity may be spaced apart from the first cavity in a width or length direction. The second cavity includes a second-first through hole formed in the first substrate layer. In addition, the second cavity includes a second-second through hole formed in the second substrate layer and vertically overlapping the second-first through hole. At this time, the second-second through-hole may have the same width as the second-first through-hole, or may have a greater width than the second-first through-hole. On the other hand, if the width of the second-second through hole is greater than the second-first through hole, the second cavity may have a step. And, in the embodiment, a driver device is placed in the second-first through hole, and a connection member connected to the driver device is placed in the second-second through hole. Accordingly, the embodiment can prevent the height of the camera module from increasing due to the height of the connection member in a structure in which the driver device is mounted using a wire bonding method, and accordingly, the overall height of the camera module can be lowered. Meanwhile, the second cavity vertically overlaps the reinforcing plate. That is, the driver device can be attached to the reinforcing plate. Accordingly, the embodiment can radiate heat generated from the driver device to the outside through the reinforcing plate, thereby improving heat dissipation of the driver device. In addition, the embodiment ensures that the heat generated from the driver device is transmitted in an opposite direction of the lens of the camera device, rather than in a direction in which the lens is placed. Accordingly, the embodiment can solve the problem of deterioration of the lens performance due to heat generated from the driver device, and the operating performance of the camera device can be further improved.

Additionally, the embodiment places the driver device in the second cavity, and accordingly, a distance between the driver device and the lens driving part can be minimized, and thus the driving reliability of the lens driving part can be improved. For example, the embodiment may minimize the signal transmission distance between the driver device and the lens driving part, and the loss of the transmitted signal can be reduced, and thus the lens driving part can be controlled more quickly and accurately.

Meanwhile, the first substrate layer may include a third through hole. At this time, the third through hole in the first embodiment may be formed penetrating the first substrate layer. For example, the third through hole may be formed to be spaced apart from the first-first and second-first through holes of the first substrate layer in a direction perpendicular to the optical axis. And, in an embodiment, the third through hole may expose at least a portion of a lower surface of the second substrate layer. At this time, although not shown in the drawing, a mounting pad (not shown) may be disposed on the lower surface of the second substrate layer exposed through the third through hole. Additionally, a passive device may be mounted on the mounting pad. At this time, in the embodiment, when mounting the passive device, at least a portion of the device is disposed in the third through hole of the first substrate layer. Accordingly, the embodiment can minimize a height occupied by the passive device, and thus the height of the camera module can be further lowered. At this time, the passive device may be arranged to overlap the lens driving part in the optical axis direction.

Additionally, the embodiment uses the protective layer of the circuit board to construct a holder for mounting the filter, and based on this, the filter is mounted directly on the circuit board. Accordingly, the embodiment does not require a separate holder for mounting the filter, thereby reducing component costs and simplifying the manufacturing process. Additionally, in an embodiment, the height of the camera module can be reduced by the height of the holder for mounting the filter, and thus the overall height of the camera module can be reduced.

### DESCRIPTION OF DRAWINGS

FIG. 1a is a cross-sectional view showing a camera module according to a comparative example.

FIG. 1b is a diagram showing an operating temperature of a driver device in a comparative example.

FIG. 2A is a cross-sectional view of a camera module according to a first embodiment.

FIG. 2B is a diagram showing an operating temperature of a driver device of a camera module of a first embodiment.

FIG. 3 is a cross-sectional view showing a camera module according to a second embodiment.

FIG. 4 is a cross-sectional view showing a camera module according to a third embodiment.

FIG. 5 is a cross-sectional view showing a camera module according to a fourth embodiment.

FIG. 6 is a cross-sectional view showing a camera module according to a fifth embodiment.

FIG. 7 is a cross-sectional view showing a camera module according to a sixth embodiment.

FIG. 8 is a perspective view of a portable terminal according to an embodiment.

FIG. 9 is a configuration diagram of the portable terminal shown in FIG. 8.

### BEST MODE

Hereinafter, embodiments of the present invention will be described in detail with reference to the accompanying drawings.

However, the spirit and scope of the present invention is not limited to a part of the embodiments described, and may be implemented in various other forms, and within the spirit and scope of the present invention, one or more of the elements of the embodiments may be selectively combined and replaced.

In addition, unless expressly otherwise defined and described, the terms used in the embodiments of the present invention (including technical and scientific terms may be construed the same meaning as commonly understood by one of ordinary skill in the art to which this invention belongs, and the terms such as those defined in commonly used dictionaries may be interpreted as having a meaning that is consistent with their meaning in the context of the relevant art. Further, the terms used in the embodiments of the present invention are for describing the embodiments and are not intended to limit the present invention.

In this specification, the singular forms may also include the plural forms unless specifically stated in the phrase, and may include at least one of all combinations that may be combined in A, B, and C when described in “at least one (or more) of A (and), B, and C”. Further, in describing the elements of the embodiments of the present invention, the terms such as first, second, A, B, (a), and (b) may be used.

These terms are only used to distinguish the elements from other elements, and the terms are not limited to the essence, order, or order of the elements. In addition, when an element is described as being “connected”, “coupled”, or “contacted” to another element, it may include not only when the element is directly “connected” to, “coupled” to, or “contacted” to other elements, but also when the element is “connected”, “coupled”, or “contacted” by another element between the element and other elements.

In addition, when described as being formed or disposed “on (over)” or “under (below)” of each element, the “on (over)” or “under (below)” may include not only when two elements are directly connected to each other, but also when one or more other elements are formed or disposed between two elements. Further, when expressed as “on (over)” or “under (below)”, it may include not only the upper direction but also the lower direction based on one element.

An optical axis direction used below is defined as an optical axis direction of a camera actuator and a lens coupled to a camera module, and a vertical direction may be defined as a direction perpendicular to the optical axis.

“Auto focus function” used below is defined as a function for automatically adjusting a focus on a subject by adjusting a distance from an image sensor and moving a lens in the optical axis direction according to the distance of the subject so that a clear image of the subject may be obtained on the image sensor.

Meanwhile, “auto focus” may correspond to “AF (Auto Focus)”. In addition, Closed-loop auto focus (CLAF) control may be defined as real-time feedback control of the lens position by sensing the distance between the image sensor and the lens to improve focus adjustment accuracy.

In addition, before a description of an embodiment of the present invention, a first direction may mean a x-axis direction shown in drawings, and a second direction may be a different direction from the first direction. For example, the second direction may mean a y-axis direction shown in the drawing in a direction perpendicular to the first direction. Also, a third direction may be different from the first and second directions. For example, the third direction may mean a z-axis direction shown in the drawing in a direction perpendicular to the first and second directions. Here, the third direction may mean an optical axis direction.

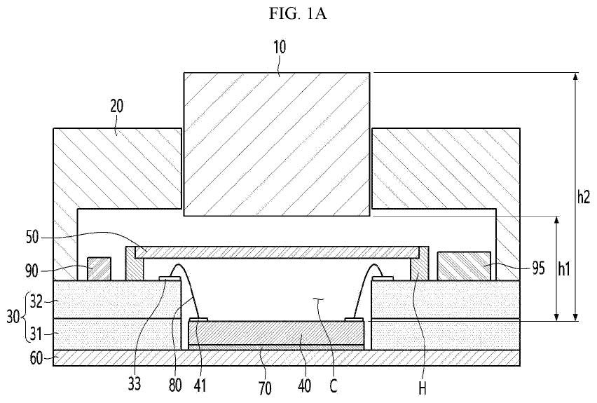

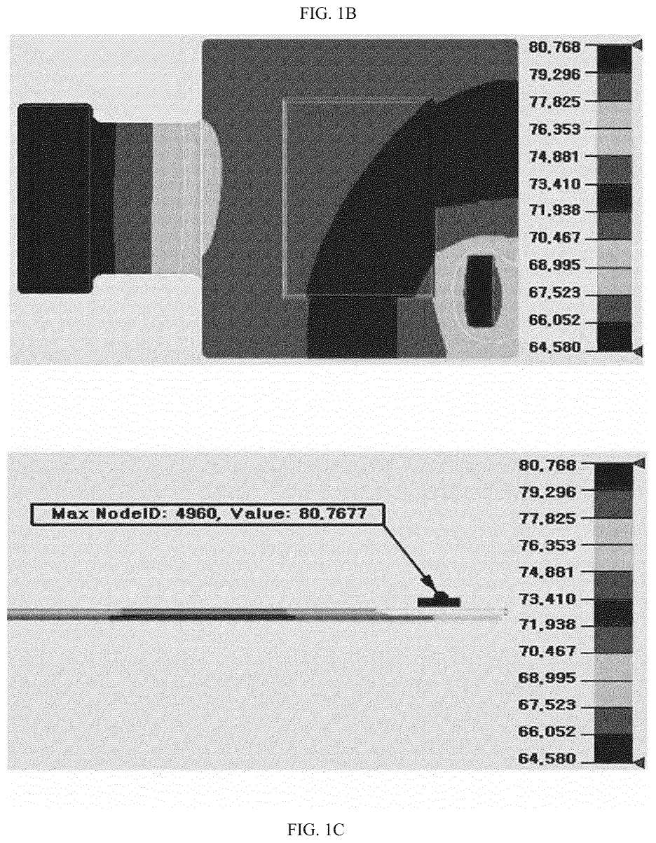

FIG. 1a is a cross-sectional view showing a camera module according to a comparative example, and FIG. 1b is a diagram showing an operating temperature of a driver device in a comparative example.

Hereinafter, before describing the camera module according to the embodiment, a camera module according to a comparative example will be described.

Referring to FIGS. 1A and 1B, the camera module according to the comparative example includes a lens module 10, a lens driving part 20, a circuit board 30, an image sensor 40, a filter 50, and a holder H, a reinforcing plate 60, an adhesive member 70, and an connection member 80.

The comparative example includes a lens module 10. The lens module 10 can provide light incident from an outside to an inside of the camera module.

The lens driving part 20 can move the lens module 10 in the optical axis direction or in a direction perpendicular to the optical axis. For example, the lens driving part 20 may drive the lens module 10 to provide an autofocus function and/or a hand shaking prevent function.

The circuit board 30 is a substrate layer on which the image sensor 40 is placed, and is connected to an external device to transmit image information acquired through the image sensor 40 to the external device.

The circuit board 30 may include a first substrate layer 31 and a second substrate layer 32 divided by an insulating layer.

Additionally, a through hole C may be formed in the first substrate layer 31 and the second substrate layer 32. Additionally, the image sensor 40 may be disposed within the through hole (C).

At this time, a reinforcing plate 60 is disposed on a lower surface of the circuit board 30.

The reinforcing plate 60 may secure the strength of the circuit board 30 and/or the image sensor 40, or may radiate heat generated from the image sensor 40 to an outside.

At this time, an adhesive member 70 may be disposed between the reinforcing plate 60 and the image sensor 40.

Meanwhile, a pad 33 may be disposed on an upper surface of the second substrate layer 32 of the circuit board 30.

Additionally, a terminal 41 of the image sensor 40 may be electrically connected to the pad 33 through a connection member 80.

Additionally, at least one device may be mounted on an upper surface of the second substrate layer 32 of the circuit board 30. The device may include a passive device 90 or a driver device 95.

Additionally, a holder H may be disposed on the upper surface of the second substrate layer 32 of the circuit board 30, and a filter 50 may be mounted on the holder H.

In the circuit board of this comparative example, the through hole C is formed to pass through an uppermost surface and a lowermost surface of the circuit board 30. Additionally, the inner wall of the through hole (C) has no steps.

Accordingly, the terminal 41 of the image sensor 40 disposed in the through hole C and the pad 33 have a structure in which they are electrically connected to each other through the connection member 80.

At this time, depending on the characteristics of the connection member 80, at least a portion of the connection member 80 has a structure that protrudes upward from an upper surface of the circuit board 30.

Additionally, in the comparative example, a holder H is placed on the circuit board 30 to mount the filter 50.

Accordingly, in the camera module of the comparative example, the first height h1 corresponding to the Flange Back Length (FBL) or the second height h2 corresponding to the Total Track Length (TTL) increases.

For example, in the camera module of the comparative example, the first height h1 should reflect a height of the holder H. Accordingly, the first height h1 in the comparative example increases by the height of the holder H. At this time, the height of the holder H is determined by the height of a portion protruding above the circuit board 30 among the heights of the connection member 80. Accordingly, the first height h1 in the comparative example increases corresponding to a protruding height of the connection member 80 and the height of the holder H according to the protruding height.

Additionally, in the camera module in the comparative example, the second height h2 should reflect the height of the holder H. Accordingly, the second height h2 in the comparative example increases by the height of the holder H. At this time, the height of the holder H is determined by the height of the portion protruding above the circuit board 30 among the heights of the connection member 80. Accordingly, the second height h2 in the comparative example increases corresponding to the protruding height of the connection member 80 and the height of the holder H according to the protruding height.

Accordingly, in the comparative example, a separate space (e.g., air gap) is required to avoid mechanical interference between the filter and the lens module. Additionally, in the comparative example, a space is also needed to avoid interference between the image sensor and the connection member. Accordingly, in the comparative example, there are restrictions on lens design (for example, TTL or FBL) depending on the height of the connection member and the height of the holder to secure the space. At this time, generally, when TTL is great and FBL is small, optical design is easy. At this time, in order to lower an overall height of the camera module, the TTL must be small, but in the comparative example, there is a limit to lowering the TTL due to restrictions in FBL.

Additionally, in the above comparative example, a passive device 90 and a driver device 95 are placed on the circuit board. At this time, the driver device 95 may be placed facing the lens on the circuit board 30. At this time, in the camera module of the comparative example, there is a problem in that heat generated in the driver device 95 is directly transferred to the lens, resulting in a decrease in the performance of the lens. Additionally, the comparative example does not include a structure for dissipating heat from the driver device 95, and as a result, there is a problem that the operating temperature of the driver device 95 is high.

For example, as shown in (a) and (b) of FIG. 1B, it was confirmed that the driver device 95 in the comparative example had an operating temperature of 80.7° C. or higher. At this time, the general driver device 95 has the characteristic that operating performance (for example, response speed) rapidly deteriorates when the operating temperature exceeds 78° C. Accordingly, in the comparative example, the operating performance of the driver device 95 decreases as the operating temperature of the device increases, and the response speed of the lens driving part decreases accordingly.

Accordingly, the embodiment provides a camera module with a new structure that can reduce the overall height (e.g., thickness of the camera module) of the camera module. Additionally, the embodiment provides a camera module with a new structure that can lower the TTL of the camera module. Additionally, the embodiment provides a camera module with a new structure that can increase the heat dissipation characteristics of the image sensor. Additionally, the embodiment provides a camera module with a new structure that can increase the heat dissipation characteristics of the driver device. Additionally, the embodiment provides a camera module that can improve resolution while improving lens performance.

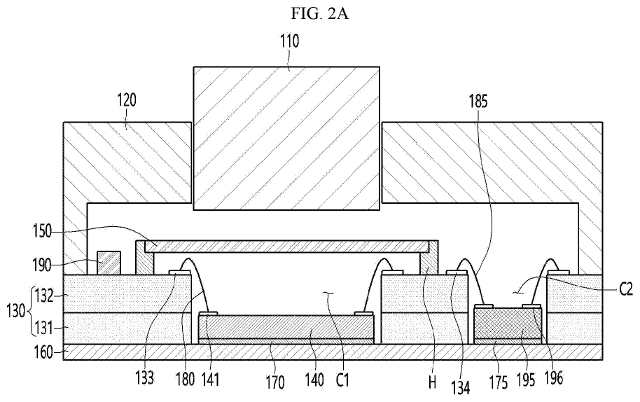

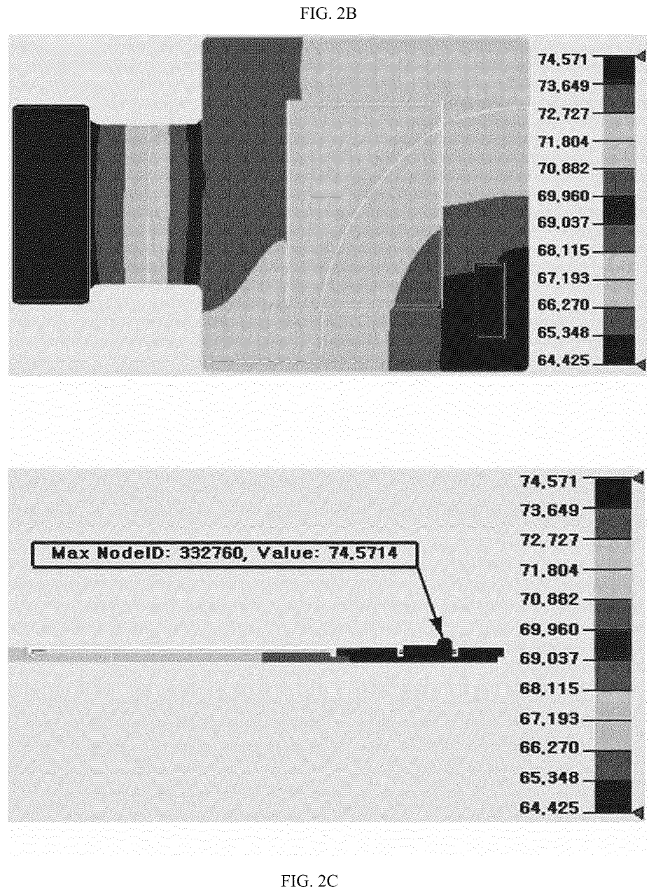

FIG. 2A is a cross-sectional view of a camera module according to a first embodiment, and FIG. 2B is a diagram showing an operating temperature of a driver device of a camera module of a first embodiment.

Referring to FIGS. 2A and 2B, a camera module of an embodiment includes a lens module 110, a lens driving part 120, a circuit board 130, an image sensor 140, a filter 150, a reinforcing plate 160, a first adhesive member 170, a first connection member 180, a passive device 190, a second adhesive member 175, a driver device 195, and a second connection member 185.

The lens module 110 may include a lens and a lens barrel that accommodates the lens. At this time, the lens module 110 may be mounted on a bobbin (not shown) constituting the lens driving part 120.

The lens driving part 120 can drive the lens module 110.

At this time, the camera module of the embodiment may be either a camera module for AF (Auto focus) or a camera module for OIS (Optical Image Stabilizer). The AF camera module is capable of performing only the autofocus function, and the OIS camera module is capable of performing the autofocus function and OIS (Optical Image Stabilizer) function.

For example, the lens driving part 120 may be a lens driving device for AF or a lens driving device for OIS, and here, the meanings of “for AF” and “for OIS” may be the same as those described in the camera module for AF and the camera module for OIS.

The lens driving part 120 may include a housing (not shown), a bobbin (not shown) disposed in the housing and on which the lens module 110 is mounted, a first coil (not shown) disposed on the bobbin, a magnet (not shown) disposed in the housing and facing the first coil, an upper elastic member (not shown) coupled to an upper part of the bobbin and an upper part of the housing, a second coil (not shown) disposed below the bobbin, a driving substrate (not shown) disposed below the second coil, and a base (not shown) disposed below the driving substrate.

Additionally, the lens driving part 120 may include a cover member (not shown) coupled to the base and accommodating the components of the lens driving part 120 together with the base.

The lens driving part 120 may include a support member (not shown) electrically connecting the driving substrate and the upper elastic member and supporting the housing with respect to the base.

The first coil and the second coil may each be electrically connected to a driving substrate and receive a driving signal (e.g., driving current) from the driving substrate. For example, the upper elastic member may include a plurality of upper springs. Additionally, the support member may be connected to a plurality of upper springs of the upper elastic member. Additionally, each of the first coil and the second coil may be electrically connected to the driving substrate through the support member. Additionally, the first coil and the second coil may receive a driving signal from the driving substrate.

The first coil may interact with the magnet to generate first electromagnetic force. And the lens module 110 may be moved in the optical axis direction by the generated first electromagnetic force. Accordingly, in the embodiment, AF driving can be implemented by controlling the displacement of the lens module 110 in the optical axis direction.

Additionally, the second coil may interact with the magnet to generate a second electromagnetic force. Additionally, the housing may be moved in a direction perpendicular to the optical axis by the generated second electromagnetic force. Accordingly, in the embodiment, hand shake correction or OIS driving can be implemented as the housing is moved in a direction perpendicular to the optical axis.

Additionally, for AF feedback driving, the lens driving part 120 of the camera module may include a sensing magnet (not shown) and an AF position sensor (e.g., a hall sensor, not shown).

Additionally, the lens driving part 120 may include a position sensor substrate (not shown) on which the AF position sensor is disposed or mounted and coupled to the housing and/or base.

In another embodiment, the AF position sensor may be placed on the bobbin and the sensing magnet may be placed on the housing. Additionally, the lens driving part 120 may include a balancing magnet disposed on the bobbin to correspond to the sensing magnet.

The AF position sensor can output an output signal based on a result of detecting the strength of the magnetic field of the sensing magnet according to the movement of the bobbin. At this time, the AF position sensor may be electrically connected to the driving substrate through an upper elastic member (or lower elastic member) and/or a support member. The driving substrate may provide a driving signal to the AF position sensor. And, the output of the AF position sensor can be transmitted to the driving substrate.

In another embodiment, the lens driving part 120 may be a lens driving device for AF, and the lens driving device for AF may include a housing, A bobbin disposed inside the housing, a coil placed on a bobbin, a magnet placed in the housing, at least one elastic member coupled to the bobbin and the housing, and a base disposed below the bobbin (or/and housing).

For example, the elastic member may include an upper elastic member and a lower elastic member described above.

A driving signal (e.g., driving current) may be provided to the coil, and the bobbin may be moved in the optical axis direction by electromagnetic force resulting from interaction between the coil and the magnet.

In another embodiment, the coil may be placed in the housing, and the magnet may be placed in the bobbin.

In addition, for AF feedback driving, the AF lens driving device may include a sensing magnet placed on the bobbin, an AF position sensor disposed in the housing (e.g., hall sensor), and a circuit board on which the AF position sensor is disposed and disposed or mounted on the housing or/and the base. In another embodiment, the AF position sensor may be placed on the bobbin and the sensing magnet may be placed on the housing.

A camera module according to another embodiment may include a housing that fixes the lens module 110 instead of the lens driving part 120, and the housing may be coupled to a separate holder (not shown). Additionally, the housing attached or fixed to the holder may not be moved, and a position of the housing may be fixed while attached to the holder.

The driving substrate may be electrically connected to the coil and the AF position sensor, a driving signal may be provided to each of the coil and the AF position sensor through the driving substrate, and an output of the AF position sensor may be transmitted to the driving substrate.

The camera module of the embodiment may include a circuit board 130.

The circuit board 130 may include a cavity.

For example, the circuit board 130 may include a plurality of cavities spaced apart in a direction perpendicular to the optical axis. For example, the circuit board 130 may include a first cavity C1 that overlaps the lens module 110 in the optical axis or vertical direction. Additionally, the circuit board 130 may include a second cavity C2 spaced apart from the first cavity C1 in a direction perpendicular to the optical axis.

The first cavity C1 may be a space for accommodating the image sensor 140. Additionally, the second cavity C2 may be a space for accommodating the driver device 195.

Additionally, the image sensor 140 may be disposed in the first cavity C1 of the circuit board 130 in the first embodiment. The image sensor 140 is located in the first cavity C1 of the circuit board 130 and may be electrically connected to the circuit board 130.

Additionally, the driver device 195 may be disposed in the second cavity C2 of the circuit board 130. The driver device 195 is disposed in the second cavity C2 of the circuit board 130 and may be electrically connected to the circuit board 130.

A reinforcing plate 160 may be placed below the image sensor 140. For example, the reinforcing plate 160 is disposed below the image sensor 140, thereby securing the rigidity of the image sensor 140. Additionally, the reinforcing plate 160 may radiate heat generated from the image sensor 140 to the outside.

Additionally, the reinforcing plate 160 may be placed below the driver device 195. For example, the reinforcing plate 160 is disposed below the driver device 195, thereby ensuring the rigidity of the driver device 195. Additionally, the reinforcing plate 160 can radiate heat generated from the driver device 195 to the outside.

Specifically, the reinforcing plate 160 may be divided into first to third regions based on a direction perpendicular to the optical axis.

For example, the reinforcing plate 160 may include a first region that overlaps the circuit board 130 in the optical axis direction or the vertical direction. Additionally, the reinforcing plate 160 may include a second region that overlaps the first cavity C1 of the circuit board 130 along the optical axis direction or the vertical direction. At this time, the second region of the reinforcing plate 160 may overlap the image sensor 140 disposed in the first cavity C1 along the optical axis direction or the vertical direction. Additionally, the reinforcing plate 160 may include a third region that overlaps the second cavity C2 of the circuit board 130 along the optical axis direction or the vertical direction. At this time, the third region of the reinforcing plate 160 may overlap the driver device 195 disposed in the second cavity C2 in the optical axis direction or the vertical direction.

The reinforcing plate 160 is a plate-like member with a preset thickness and hardness, and can stably support the image sensor 140. The reinforcing plate 160 is possible to prevent the image sensor 140 and the driver device 195 from being destroyed by external impact or contact. Additionally, the reinforcing plate 160 may have a heat dissipation effect by dissipating heat generated from the image sensor 140 and the driver device 195 to the outside, and for this purpose, the reinforcing plate 160 may be formed of a metal material with high thermal conductivity.

For example, the reinforcing plate 160 may include SUS or aluminum, but the embodiment is not limited thereto. For example, the reinforcing plate 160 in another embodiment may be formed of glass epoxy, plastic, or synthetic resin.

Additionally, the reinforcing plate 160 may serve as a ground to protect the camera module from ESD (Electrostatic Discharge Protection) by being electrically connected to the ground terminal (not shown) of the circuit board 130. To this end, the circuit board 130 includes a ground terminal (not shown), and the ground terminal is disposed on a lower surface of the circuit board 130 and may be in contact with or connected to the reinforcing plate 160.

Meanwhile, the reinforcing plate 160 may be placed on the lower surface of the circuit board 130. For example, an adhesive member (not shown) may be placed between the lower surface of the circuit board 130 and the reinforcing plate 160. Accordingly, the reinforcing plate 160 may be attached or fixed to the lower surface of the circuit board 130.

Meanwhile, a first adhesive member 170 may be disposed between the image sensor 140 and the reinforcing plate 160. Additionally, a second adhesive member 175 may be disposed between the driver device 195 and the reinforcing plate 160.

The first adhesive member 170 is disposed on the lower surface of the image sensor 140, thereby allowing the image sensor 140 to be fixed or coupled to the reinforcing plate 160.

As an example, the first adhesive member 170 is disposed in the first cavity C1 of the circuit board 130, so that the image sensor 140 can be attached to the reinforcing plate 160 within the first cavity C1.

At this time, the first adhesive member 170 may have a width narrower than the width of the first cavity C1 of the circuit board 130.

That is, the first adhesive member 170 may be disposed on a second region of the reinforcing plate 160. At this time, the first adhesive member 170 may be disposed to cover a portion of the second region of the reinforcing plate 160. Accordingly, the second region of the reinforcing plate 160 may include a second-first region where the first adhesive member 170 is disposed, and a second-second region excluding the second-first region.

The circuit board 130 may be composed of multiple layers. For example, the circuit board 130 may include a first substrate layer 131 and a second substrate layer 132. In addition, the first cavity C1 in the first embodiment may be formed by commonly passing through the first substrate layer 131 and the second substrate layer 132. For example, the first cavity C1 may include a first-first through hole passing through the first substrate layer 131 and a first-second through hole through the second substrate layer 132. Also, in the first embodiment, the first-first through hole and the first-second through hole may have the same width.

Additionally, the first adhesive member 170 may be disposed within the first-first through hole of the first cavity C1. At this time, the first adhesive member 170 may have a width smaller than the first-first through hole of the first cavity C1. Accordingly, the first adhesive member 170 may be spaced apart from the sidewall of the first substrate layer 131 including the first-first through hole. Accordingly, in the embodiment, it is possible to prevent the circuit board 130 from being damaged during a process of applying the first adhesive member 170.

Alternatively, in an embodiment, the first adhesive member 170 may have a width equal to the width of the first-first through hole of the first substrate layer 131. Accordingly, in the embodiment, the first adhesive member 170 can be used to prevent foreign substances from entering the first cavity C1 of the circuit board 130.

Additionally, the second adhesive member 175 is disposed on the lower surface of the driver device 195, thereby allowing the driver device 195 to be fixed or coupled to the reinforcing plate 160.

As an example, the second adhesive member 175 is disposed in the second cavity C2 of the circuit board 130, so that the driver device 195 can be attached to the reinforcing plate 160 within the second cavity C2.

For example, the second adhesive member 175 may have a width narrower than the width of the second cavity C2 of the circuit board 130.

That is, the second adhesive member 175 may be disposed on the third region of the reinforcing plate 160. At this time, the second adhesive member 175 may be disposed to cover a portion of the third region of the reinforcing plate 160. Accordingly, the third region of the reinforcing plate 160 may include a third-first region where the second adhesive member 175 is disposed, and a third-second region excluding the third-first region.

Additionally, the second cavity C2 may be formed by commonly passing through the first substrate layer 131 and the second substrate layer 1332. For example, the second cavity C2 may include a second-first through hole passing through the first substrate layer 131 and a second-second through hole passing through the second substrate layer 132. Also, in the first embodiment, the second-first through hole and the second-second through hole may have the same width.

Also, the second adhesive member 175 may be disposed in the second-first through hole of the second cavity C2. At this time, the second adhesive member 175 may have a width smaller than the second-first through hole of the second cavity C2. Accordingly, the second adhesive member 175 may be spaced apart from a sidewall of the first substrate layer 131 including the second-first through hole. Accordingly, in the embodiment, it is possible to prevent the circuit board 130 from being damaged during a process of applying the second adhesive member 175.

Alternatively, in an embodiment, the second adhesive member 175 may have a width equal to the width of the second-first through hole of the first substrate layer 131. Accordingly, in the embodiment, the second adhesive member 175 can be used to prevent foreign substances from entering the first cavity C1 of the circuit board 130.

The circuit board 130 may be equipped with various circuits, elements, and control units to convert the image signal formed on the image sensor 140 into an electrical signal and then transmit it to an external device. Additionally, a circuit pattern that is electrically connected to the image sensor 140 and various devices may be formed on the circuit board 130. For example, a first pad 133 electrically connected to the image sensor 140 may be formed on the circuit board 130. Additionally, a mounting pad (not shown) on which the passive device 190 is mounted may be formed on the circuit board 130. This will be explained in detail below.

In the first embodiment, the first pad 133 may be disposed on an upper surface of the second substrate layer 132.

Additionally, the driver device 195 may be a control device that controls the overall operation of the camera device. For example, the driver device 195 may control the operation of the lens driving part 120.

Additionally, a second pad 134 connected to the driver device 195 may be formed on the circuit board 130.

The camera module may include a filter 150. At this time, in the first embodiment, the filter 150 may be attached to the holder H disposed on the circuit board 130.

The filter 150 may serve to block light of a specific frequency band from light passing through the lens module 110 from being incident on the image sensor 140.

For example, the filter 150 may be an infrared filter, but is not limited thereto. Additionally, the filter 150 may be arranged parallel to the horizontal direction perpendicular to the optical axis (e.g., x-y plane).

Meanwhile, in an embodiment, the filter 150 may include a blocking member (not shown). The blocking member may be disposed in an edge region of an upper surface of the filter 150. The blocking member may be referred to as a masking member. The blocking member is disposed at an edge region of the upper surface of the filter, so that at least a portion of light passing through the lens module 110 and incident toward an edge region of the filter 150 may be blocked from passing through the filter 150. The blocking member may be coupled or attached to an upper surface of the filter 150. The filter 150 may be formed in a square shape when viewed in the optical axis direction, and the blocking member may be formed symmetrically with respect to the filter 150 along each side of the upper surface of the filter 150. The blocking member may be formed to have a constant width on each side of the upper surface of the filter 150. The blocking member may be made of an opaque material. For example, the blocking member may be made of an opaque adhesive material applied to the filter 150, or may be provided in the form of a film attached to the filter 150.

Hereinafter, the circuit board 130 of the embodiment will be described in more detail.

The circuit board 130 of the embodiment may include a first substrate layer 131 and a second substrate layer 132.

At this time, the first substrate layer 131 and the second substrate layer 132 are not separate substrates bonded to each other, but rather mean that a plurality of insulating layers are stacked in the optical axis direction to form a single circuit board.

However, the embodiment is not limited thereto, and the circuit board 130 may be formed by separately manufacturing a plurality of substrate layers and then bonding them.

The first substrate layer 131 and the second substrate layer 132 may each include at least one insulating layer. Preferably, the first substrate layer 131 may include a plurality of insulating layers. Additionally, the second substrate layer 132 may include a plurality of insulating layers. However, in FIG. 2, for convenience of explanation, each of the first substrate layer 131 and the second substrate layer 132 is shown as consisting of one layer.

The insulating layers constituting the first substrate layer 131 and the second substrate layer 132 may be rigid insulating layers. For example, the circuit board 130 may include a rigid region including a rigid insulating layer and a flexible region including a flexible insulating layer. And, in the circuit board 130, the region where the image sensor 140 and the driver device 195 are placed is a rigid region with a certain rigidity, and accordingly, the insulating layer constituting the first substrate layer 131 and the second substrate layer 132 may also be a rigid insulating layer. For example, the insulating layer constituting the first substrate layer 131 and the second substrate layer 132 may be a rigid insulating layer having greater rigidity or hardness than the flexible insulating layer, and for example, may be a prepreg. At this time, the insulating layer may be referred to as an insulating film or an insulating film.

At this time, a circuit pattern layer may be disposed on a surface of each insulating layer constituting the first substrate layer 131 and the second substrate layer 132. The circuit pattern layer may include a first pad 133 on which the image sensor 140 is mounted. Additionally, the circuit pattern layer may include a second pad 134 on which the driver device 195 is mounted.

Additionally, the circuit pattern layer may include traces (not shown) that are signal lines connected to the first pad 133 and the second pad 134. Additionally, the circuit pattern layer may further include a third pad on which a passive device 190 is mounted.

The circuit pattern layer may be formed of at least one metal material selected from among gold (Au), silver (Ag), platinum (Pt), titanium (Ti), tin (Sn), copper (Cu), and zinc (Zn). In addition, the circuit pattern layer may be formed of paste or solder paste including at least one metal material selected from among gold (Au), silver (Ag), platinum (Pt), titanium (Ti), tin (Sn), copper (Cu), and zinc (Zn), which are excellent in bonding force. Additionally, the circuit pattern layer may include at least one surface treatment layer formed of a metal material with high wire bonding properties.

The circuit pattern layer can be formed using an additive process, a subtractive process, a modified semi additive process (MSAP) and a semi additive process (SAP), which is a typical circuit board manufacturing process, and a detailed description will be omitted here.

In the first embodiment, the first pad 133 may not overlap the image sensor 140 in the optical axis direction. For example, in the first embodiment, the first pad 133 and the terminal 141 of the image sensor 140 are not directly connected to each other, but may have a structure connected through a separate first connection member 180. For example, the first pad 133 and the terminal 141 of the image sensor 140 may be connected to each other using a wire bonding method through the first connection member 180.

Additionally, the second pad 134 may not overlap the driver device 195 in the optical axis direction. For example, the second pad 134 and the terminal 196 of the driver device 195 may not be directly connected to each other, but may be connected through a separate second connection member 185. For example, the second pad 134 and the terminal 196 of the driver device 195 may be connected to each other using a wire bonding method through the second connection member 185.

At this time, as described above, the first substrate layer 131 and the second substrate layer 132 include first and second cavities C1 and C2.

For example, the first substrate layer 131 may include a first-first through hole that is a part of the first cavity C1. For example, the first substrate layer 131 may include a first-first through hole passing through the upper surface of the first substrate layer 131 and the lower surface opposite to the upper surface.

Additionally, the second substrate layer 132 may include a first-second through hole that is a remaining portion of the first cavity C1. For example, the second substrate layer 132 may include a first-second through hole passing through the upper surface of the second substrate layer 132 and the lower surface opposite to the upper surface.

At this time, the first-first through hole and the first-second through hole may overlap along the optical axis or vertically. For example, the first-first through hole and the first-second through hole are formed by simultaneously processing the first substrate layer 131 and the second substrate layer 132, and thus may have the same width.

The first-first through hole of the first substrate layer 131 may provide a space where the image sensor 140 is placed. For example, the first-first through hole may be a receiving portion that accommodates the image sensor 140.

Additionally, the first-second through hole of the second substrate layer 132 may provide a space where the first connection member 180 is disposed. For example, the first-second through hole may be a receiving portion that accommodates the first connection member 180. That is, the first connection member 180 in the first embodiment may electrically connect the terminal 141 of the image sensor 140 and the first pad 133 of the circuit board 130 in the state of being placed within the first-second through hole above.

Additionally, the first substrate layer 131 may include a second-first through hole that is a part of the second cavity C2. For example, the first substrate layer 131 may include a second-first through hole passing through the upper surface of the first substrate layer 131 and the lower surface opposite to the upper surface. The second-first through-hole may be spaced apart from the first-first through-hole in a direction perpendicular to the optical axis.

Additionally, the second substrate layer 132 may include a second-second through hole, which is a remaining portion of the second cavity C2. For example, the second substrate layer 132 may include a second-second through hole passing through the upper surface of the second substrate layer 132 and the lower surface opposite to the upper surface.

At this time, the second-first through hole and the second-second through hole may overlap along the optical axis or vertically. For example, the second-first through hole and the second-second through hole are formed by simultaneously processing the first substrate layer 131 and the second substrate layer 132, and thus may have the same width.

The second-first through hole of the first substrate layer 131 may provide a space where the driver device 195 is placed. For example, the second-first through hole may be a receiving portion that accommodates the driver device 195.

Additionally, the second-second through hole of the second substrate layer 132 may provide a space where the second connection member 185 is disposed. For example, the second-second through hole may be a receiving portion that accommodates the second connection member 185. That is, the second connection member 185 in the first embodiment may electrically connect the terminal 196 of the driver device 195 and the second pad 134 of the circuit board 130 in the state of being disposed in the second-second through-hole.

Meanwhile, the first pad 133 and the second pad 134 in the first embodiment are disposed on the second substrate layer 132 of the circuit board 130. Accordingly, at least a portion of the first connection member 180 and the second connection member 185 may be positioned higher than the upper surface of the circuit board.

Accordingly, the first embodiment provides a holder H, and the filter 150 may be disposed on the holder H.

The first connection member 180 and the second connection member 185 may be wires. For example, the first connection member 180 and the second connection member 185 may be formed of a conductive material, for example, any one of gold (Au), silver (Ag), copper (Cu), and copper alloy. These conductive materials may have the property of reflecting light. At this time, the light passing through the filter may be reflected by the first connection member 180 and the second connection member 185, and such reflected light may cause instantaneous flashing, for example, a flare phenomenon. Additionally, this flare phenomenon may distort the image formed on the image sensor 140 or deteriorate image quality. Accordingly, the blocking member disposed on the filter can block light directed to the first connection member 180 and the second connection member 185. Accordingly, in the embodiment, even if the first connection member 180 and the second connection member 185 are disposed between the filter and the image sensor 140, light directed to the first connection member 180 and the second connection member 185 can be blocked through the blocking member. Accordingly, the occurrence of the flare phenomenon described above can be prevented, and problems such as distortion or deterioration of image quality of the image formed on the image sensor 140 can be solved.

Meanwhile, the second substrate layer 132 may include a plurality of insulating layers. At this time, the plurality of insulating layers may include a protective layer such as solder resist. The protective layer is disposed on an outermost side (e.g., the uppermost side) of the second substrate layer 132, and accordingly, the protective layer serves to protect the surface of the insulating layer constituting the second substrate layer 132 or the surface of the circuit pattern layer. Additionally, the holder H may be placed on the protective layer of the second substrate layer 132.

Meanwhile, the embodiment may include a passive device 190 disposed on the second substrate layer 132 of the circuit board 130. The passive device 190 may be a support device that supports the function of a driver device that controls the operation of the lens driving part 120 of the embodiment.

According to the first embodiment as described above, the camera module includes a circuit board.

And, the circuit board 130 includes a first cavity C1 and a second cavity C2. Additionally, a reinforcing plate is disposed below the circuit board 130.

Accordingly, the image sensor of the embodiment may be disposed on the reinforcing plate overlapping the first cavity C1. Through this, in the embodiment, the rigidity of the image sensor can be secured, and further, heat generated from the image sensor can be discharged to the outside through the reinforcing plate.

Furthermore, in an embodiment, the second cavity may be spaced apart from the first cavity in a width or length direction. The second cavity includes a second-first through hole formed in the first substrate layer. Additionally, the second cavity includes a second-second through hole formed in the second substrate layer and vertically overlapping the second-first through hole. At this time, the second-second through hole may have the same width as the second-first through hole, but may have a different width. Meanwhile, when the width of the second-second through hole is larger than the second-first through hole, the second cavity may have a step. And, in the embodiment, a driver device is placed in the second-first through hole, and a connection member connected to the driver device is placed in the second-second through hole. Accordingly, in the embodiment, in a structure in which a driver device is mounted using a wire bonding method, it is possible to prevent an increase in the height of the camera module due to the height of the connection member, and thereby reduce the overall height of the camera module.

Meanwhile, the second cavity vertically overlaps the reinforcing plate. That is, the driver device can be attached to the reinforcing plate. Accordingly, in the embodiment, heat generated from the driver device can be discharged to the outside through the reinforcing plate, thereby improving heat dissipation of the driver device. Specifically, as shown in (a) and (b) of FIG. 2B, when the driver device 195 is placed on the reinforcing plate 160, it was confirmed that the operating temperature of the driver device (195) was lowered compared to the comparative example. In addition, it was confirmed that the operating temperature of the driver device 195 was 74.6° C., which did not affect reliability.

In addition, in the embodiment, the heat generated from the driver device is transmitted in an opposite direction rather than a direction in which the lens of the camera device is placed, thereby solving the problem of deterioration of the performance of the lens due to heat generated from the driver device. As a result, the operating performance of the camera device can be further improved.

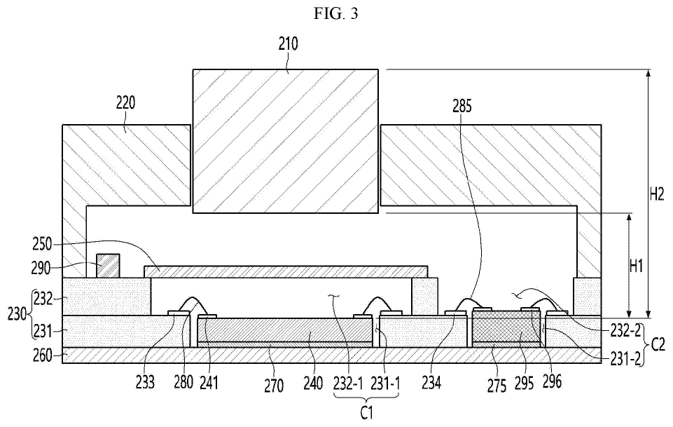

FIG. 3 is a cross-sectional view showing a camera module according to a second embodiment.

Referring to FIG. 3, the camera module of the second embodiment includes a lens module 210, a lens driving part 220, a circuit board 230, an image sensor 240, a filter 250, a reinforcing plate 260, a first adhesive member 270, a first connection member 280, a passive device 290, a second adhesive member 275, a driver device 295, and a second connection member 285.

At this time, in the camera module of the second embodiment, the lens module 210 and the lens driving part 220 are substantially the same as the components with a same name in FIG. 2, so detailed description thereof will be omitted.

The cavities C1 and C2 included in the circuit board 230 in the second embodiment may have a step in a horizontal direction perpendicular to the optical axis.

However, the embodiment is not limited thereto, and at least one of the first cavity and the second cavity of a step structure described below may have the cavity structure shown in FIG. 2.

Hereinafter, it will be explained that both the first cavity C1 and the second cavity C2 have a stepped structure.

The circuit board 230 of the embodiment may include a first substrate layer 231 and a second substrate layer 232.

At this time, the first substrate layer 231 and the second substrate layer 232 may not be separate substrates bonded to each other, but may be one substrate divided into a plurality of substrates based on the through holes forming the cavity. However, the embodiment is not limited thereto, and the circuit board 230 may be formed by manufacturing a plurality of substrates and then bonding them.

In the second embodiment, the first pad 233 may not overlap the image sensor 240 in the optical axis direction. For example, in the second embodiment, the first pad 233 and the terminal 241 of the image sensor 240 are not directly connected to each other, but may have a structure connected through a separate first connection member 280. For example, the first pad 233 and the terminal 241 of the image sensor 240 may be connected to each other through a first connection member 280 using a wire bonding method.

At this time, as described above, the first substrate layer 231 and the second substrate layer 232 include a first cavity C1. For example, the first substrate layer 231 may include a first-first through hole 231-1 that is part of the cavity. For example, the first substrate layer 231 may include a first-first through hole 231-1 passing through the upper surface of the first substrate layer 231 and the lower surface opposite to the upper surface.

Additionally, the second substrate layer 232 may include a second-second through hole 232-1, which is a remaining portion of the first cavity C1. For example, the second substrate layer 232 may include a first-second through hole 232-1 passing through the upper surface of the second substrate layer 232 and the lower surface opposite to the upper surface.

At this time, the first-first through-hole 231-1 and the first-second through-hole 232-1 may at least partially overlap each other in the optical axis direction. For example, at least a portion of the first-second through-hole 232-1 may overlap with the first-first through-hole 231-1 in the optical axis direction. For example, a remaining portion of the first-second through-hole 232-1 may not overlap with the first-first through-hole 231-1 in the optical axis direction. For example, a width of the first-first through hole 231-1 may be different from a width of the first-second through hole 232-1. Preferably, the width of the first-first through hole 231-1 may be smaller than the width of the first-second through hole 232-1.

The first-first through hole 231-1 of the first substrate layer 231 may provide a space where the image sensor 240 is placed. For example, the first-first through hole 231-1 may be a receiving portion that accommodates the image sensor 140.

Additionally, the first-second through hole 232-1 of the second substrate layer 232 may provide a space where the first connection member 280 is disposed. For example, the first-second through hole 232-1 may be a receiving portion that accommodates the first connection member 280. The first connection member 280 in the second embodiment may electrically connect the terminal 241 of the image sensor 240 to the first pad 233 of the circuit board 230 while disposed in the first-second through hole 232-1.

As described above, in the embodiment, the circuit board 230 may be divided into a first substrate layer 231 and a second substrate layer 232. In addition, a first-first through hole 231-1 may be formed in the first substrate layer 231, and a first-second through-hole 232-1 may be formed in the second substrate layer 232, at least partially overlapping the first-first through-hole 231-1 in the optical axis direction. At this time, the first-first through hole 231-1 and the first-second through hole 232-1 may have different widths. For example, the first-first through hole 231-1 may have a smaller size than the first-second through hole 232-1. For example, the cavity of the circuit board 230 including the first-first through hole 231-1 and the first-second through hole 232-1 may have a step.

Subsequently, in the embodiment, the image sensor 240 may be placed in the first-first through hole 231-1 of the first substrate layer 231. For example, a reinforcing plate 260 may be attached to the lower surface of the first substrate layer 231. Also, the image sensor 240 can be attached to the upper surface of the reinforcing plate 260 exposed through the first-first through hole 231-1 of the first substrate layer 231. Through this, the image sensor 240 in the embodiment can be positioned within the first-first through hole 231-1 of the first substrate layer 231 while attached to the reinforcing plate 260.

Additionally, in the embodiment, the first-second through-hole 232-1 of the second substrate layer 232 may be larger than the first-first through-hole 231-1 of the first substrate layer 231. Accordingly, at least a portion of the upper surface of the first substrate layer 231 may overlap the first-second through hole 232-1. For example, the first substrate layer 231 may include a upper surface region exposed through the first-second through hole 232-1 of the second substrate layer 232. And, in the embodiment, the first pad 233 may be formed in the upper surface region of the first substrate layer 231 exposed through the first-second through hole 232-1.

At this time, the upper surface region of the first substrate layer 231 exposed through the first-second through hole 232-1 may not overlap the image sensor 240 in the optical axis direction. Through this, the first pad 233 and the terminal 241 of the image sensor 240 in the embodiment may be arranged at a certain distance from each other in a direction perpendicular to the optical axis. And, in an embodiment, the first pad 233 and the terminal 241 of the image sensor 240 may be connected using the first connection member 280. At this time, the first connection member 280 does not protrude above the upper surface of the circuit board 230. For example, an uppermost end of the first connection member 280 may be located lower than the uppermost end of the circuit board 230. For example, the first connection member 280 may be located within the first-second through hole 232-1 of the second substrate layer 232.

Additionally, the first substrate layer 231 and the second substrate layer 232 include a second cavity C2. For example, the first substrate layer 231 may include a second-first through hole 231-2 that is a part of the second cavity. For example, the first substrate layer 231 may include a second-first through hole 231-2 passing through the upper surface of the first substrate layer 231 and the lower surface opposite to the upper surface.

Additionally, the second substrate layer 232 may include a second-second through hole 232-2, which is a remaining portion of the second cavity C2. For example, the second substrate layer 232 may include a second-second through hole 232-2 passing through the upper surface of the second substrate layer 232 and the lower surface opposite to the upper surface.

At this time, the second-first through-hole 231-2 and the second-second through-hole 232-2 may at least partially overlap each other in the optical axis direction. For example, at least a portion of the second-second through-hole 232-2 may overlap the second-first through-hole 231-2 in the optical axis direction. For example, a remaining portion of the second-second through-hole 232-2 may not overlap with the second-first through-hole 231-2 in the optical axis direction. For example, the width of the second-first through hole 231-2 may be different from the width of the second-second through hole 232-2. Preferably, the width of the second-first through hole 231-2 may be smaller than the width of the second-second through hole 232-2.

The second-first through hole 231-2 of the first substrate layer 231 may provide a space where the driver device 195 is placed. For example, the second-first through hole 231-2 may be a receiving portion that accommodates the driver device 295.

Additionally, the second-second through hole 232-2 of the second substrate layer 232 may provide a space where the second connection member 285 is disposed. For example, the second-second through hole 232-2 may be a receiving portion that accommodates the second connection member 285. That is, the second connection member 285 in the second embodiment may electrically connect the terminal 296 of the driver device 295 to the second pad 234 of the circuit board 230 while disposed in the second-second through hole 232-2.

That is, the second-first through hole 231-2 and the second-second through hole 232-2 may have different widths. For example, the second-first through hole 231-2 may have a smaller size than the second-second through hole 232-2. For example, the second cavity C2 of the circuit board 230 including the second-first through hole 231-2 and the second-second through hole 232-2 may have a step.

Subsequently, the embodiment may place the driver device 295 in the second-first through hole 231-2 of the first substrate layer 231. For example, a reinforcing plate 260 may be attached to the lower surface of the first substrate layer 231. Additionally, the driver device 295 can be attached to the upper surface of the reinforcing plate 260 exposed through the second-first through hole 231-2 of the first substrate layer 231. Through this, the image sensor 240 in the embodiment can be positioned within the second-first through hole 231-2 of the first substrate layer 231 while attached to the reinforcing plate 260.

Additionally, in the embodiment, the second-second through-hole 232-2 of the second substrate layer 232 may be larger than the second-first through-hole 231-2 of the first substrate layer 231. Accordingly, at least a portion of the upper surface of the first substrate layer 231 may overlap the second-second through hole 232-2. For example, the first substrate layer 231 may include a upper surface region exposed through the second-second through hole 232-2 of the second substrate layer 232. And, in the embodiment, the second pad 234 may be formed in the upper surface region of the first substrate layer 231 exposed through the second-second through hole 232-2.

In an embodiment, the second pad 234 and the terminal 296 of the driver device 295 may be connected using the second connection member 285. At this time, the second connection member 285 does not protrude above an upper surface of the circuit board 230. For example, an uppermost end of the second connection member 285 may be located lower than an uppermost end of the circuit board 230. For example, the second connection member 285 may be located within the second-second through hole 232-2 of the second substrate layer 232. Through this, in the embodiment, the distance between the lens driving part and the driver device can be reduced, and thus the operation speed of the lens driving part can be improved.

Meanwhile, in the second embodiment, the filter 250 may be directly attached to the upper surface of the second substrate layer 232 of the circuit board 230.

For example, the second substrate layer 232 may include a plurality of insulating layers.

At this time, the plurality of insulating layers may include a protective layer such as solder resist. The protective layer is disposed on the outermost side (e.g., uppermost side) of the second substrate layer 232, and accordingly, the protective layer can serve to protect the surface of the insulating layer constituting the second substrate layer 232 or the surface of the circuit pattern layer.

Accordingly, in an embodiment, a seating groove in which the filter 250 is seated may be formed in the protective layer. For example, the protective layer may be disposed at a certain height, and accordingly may include a groove (not shown) recessed in the downward direction on the upper surface. Additionally, the filter 250 may be attached to the second substrate layer 232 using the groove formed in the protective layer as a seating portion.

Accordingly, according to the camera module of the second embodiment, a separate holder for mounting the filter 250 may not be provided. For example, in the comparative example, a separate holder for placing the filter was placed on an upper portion of the circuit board, and the filter was mounted on the holder using the holder as a seating part.

In contrast, according to the second embodiment of the present application, a holder for mounting the filter 250 is constructed using the protective layer of the circuit board, and accordingly, the filter 250 is mounted directly on the circuit board 230. Accordingly, the embodiment does not require a separate holder for mounting the filter 250, thereby reducing component costs and simplifying the manufacturing process. Additionally, the embodiment can reduce the height of the camera module by the height of the holder for mounting the filter, thereby lowering the overall height of the camera module. This is because the first and second cavities constituting the circuit board 230 have a step difference, and a part of the step difference (e.g. first-second through hole or second-second through hole) between the first and second cavities is used as a space where the first connection member 280 and the second connection member 285 are arranged.

According to the second embodiment as described above, the camera module may include a circuit board.

In addition, the circuit board 230 may include a first substrate layer 231 and a second substrate layer 232. In addition, the first substrate layer 231 includes a first-first through hole 231-1, and the second substrate layer 232 may includes a first-second through hole 232-1 including at least a portion overlapping with the first-first through hole 231-1 in the optical axis direction. At this time, the first-second through hole 232-1 may have a width greater than the width of the first-first through hole 231-1. Accordingly, the cavity including the first-first through hole 231-1 and the first-second through hole 232-1 may have a step. And, in the embodiment, the image sensor 240 is placed in the first-first through hole 231-1, and a first connection member 280 connected to the image sensor 240 may be disposed in the first-second through hole 232-1. Accordingly, the embodiment can prevent the height of the camera module from increasing due to the height of the first connection member 280 in a structure in which the image sensor 240 is mounted using a wire bonding method, and accordingly, the overall height of the camera module can be lowered. Furthermore, the embodiment does not need to consider the height of the first connection member 280 in order to place the filter 250, and accordingly, the filter 250 can be placed directly on the circuit board 230. Accordingly, the embodiment may remove the holder for placing the filter 250. Accordingly, by removing the first-first through hole 231-1 and the holder, the overall height of the camera module can be lowered by the height of the holder.

Accordingly, in the camera module of the second embodiment, the first height H1 corresponding to the Flange Back Length (FBL) or the second height H2 corresponding to the Total Track Length (TTL) may be reduced compared to the comparative example in FIG. 1.

For example, in the camera module of the comparative example, the first height h1 corresponding to FBL (Flange Back Length) or the second height h2 corresponding to TTL (Total Track Length) reflects the height of the connection member or the height of the holder on which the filter is mounted, and accordingly had to be increased by the height of the connection member and the height of the holder.

Differently, the second embodiment allows the first connection member 280 to be disposed within the cavity of the circuit board 130, and accordingly, the filter 250 is allowed to have a structure that is directly mounted on the circuit board 230. Accordingly, the first height H1 corresponding to the Flange Back Length (FBL) and the second height H2 corresponding to the Total Track Length (TTL) may be reduced compared to the comparative example.

Furthermore, the embodiment allows not only the first connection member 280 but also the second connection member 285 to have a structure disposed within the cavity of the circuit board, and accordingly, the first height H1 corresponding to the Flange Back Length (FBL) and the second height H2 corresponding to the Total Track Length (TTL) may be further reduced.

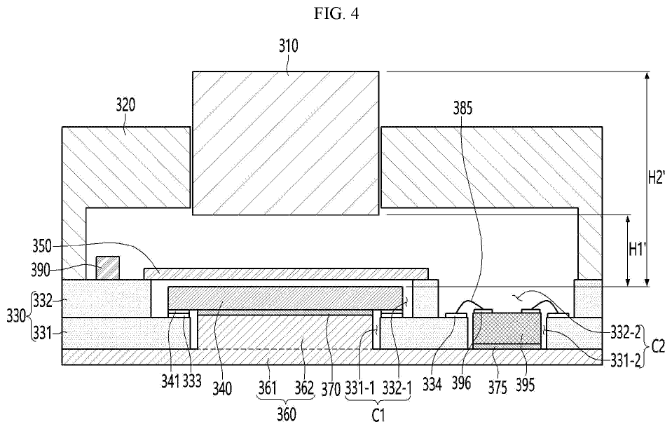

FIG. 4 is a cross-sectional view showing a camera module according to a third embodiment.

Referring to FIG. 4, the camera module of the third embodiment includes a lens module 310, a lens driving part 320, a circuit board 330, an image sensor 340, a filter 350, a reinforcing plate 360, a first adhesive member 370, a first connection member 380, a passive device 390, a second adhesive member 375, a driver device 395, and a second connection member 385.

At this time, in the camera module of the third embodiment, since the lens module 310, the lens driving part 320, the circuit board 330, the image sensor 340, the filter 350, the reinforcing plate 360, the first adhesive member 370, the first connection member 380, the passive device 390, the second adhesive member 375, the driver device 395, and the second connection member 385 are substantially the same as the component with the same name in FIG. 3, detailed description thereof will be omitted.

The camera module according to the third embodiment of FIG. 4 differs from the camera module of the second embodiment of FIG. 3 in that the image sensor is arranged using a flip chip bonding method.

The circuit board 330 in the third embodiment includes the first substrate layer 331 and the second substrate layer 332. Additionally, the first substrate layer 331 may include a first-first through hole 331-1, which is a part of the cavity. And, the second substrate layer 332 may include a first-second through hole 332-1. At this time, the first-first through-hole 331-1 and the first-second through-hole 332-1 may at least partially overlap each other in the optical axis direction. For example, at least a portion of the first-second through-hole 332-1 may overlap with the first-first through-hole 331-1 in the optical axis direction. For example, a remaining portion of the first- second through-hole 332-1 may not overlap with the first-first through-hole 331-1 in the optical axis direction. For example, a width of the first-first through hole 331-1 may be different from a width of the first-second through hole 332-1. Preferably, the width of the first-first through hole 331-1 may be smaller than the width of the first-second through hole 332-1.

The first-first through hole 331-1 of the first substrate layer 331 may provide a space where a reinforcing plate 360 attached to the image sensor 340 is placed. For example, the first-first through hole 331-1 of the first substrate layer 331 may be a receiving portion that accommodates the reinforcing plate 360. Accordingly, at least a portion of the reinforcing plate 360 may be disposed within the first-first through hole 331-1 of the first substrate layer 331. As an example, the entire region of the reinforcing plate 360 may be disposed within the first-first through hole 331-1 of the first substrate layer c331. As another example, some regions of the reinforcing plate 360 are disposed within the first-first through hole 331-1 of the first substrate layer 331, and a remaining region may protrude downward from the first substrate layer 331.

That is, in the second embodiment, the image sensor 240 is disposed in the first-first through hole 231-1.

Alternatively, a reinforcing plate 360 may be disposed in the first-first through hole 331-1 in the third embodiment.

For this purpose, the reinforcing plate 360 may include a first plate portion 361 attached to the lower surface of the first substrate layer 331, and a second plate portion 362 protruding from the first plate portion 361.

At this time, the first plate portion 361 and the second plate portion 362 may be formed as one piece, or alternatively, may be formed by attaching separate components.

For example, the reinforcing plate 360 in the embodiment may include the first plate portion 361 and the second plate portion 362 by etching and removing a portion of a plate having a certain thickness. Alternatively, the reinforcing plate 360 in the embodiment may be implemented by preparing a first plate portion 361 and attaching a second plate portion 362 on the first plate portion 361.

At this time, the first plate portion 361 is disposed on the lower surface of the first substrate layer 331. Additionally, the second plate portion 362 protrudes from the upper surface of the first plate portion 361 and may be disposed in the first-first through hole 331-1 of the first substrate layer 331.

Accordingly, the first-first through hole 331-1 of the first substrate layer 331 in the third embodiment may be a receiving portion in which a portion of the reinforcing plate 360 is accommodated. At this time, the width of the second plate portion 362 may be smaller than the width of the first-first through hole 331-1. Accordingly, in the process of placing the second plate portion 362 in the first-first through hole 331-1 of the first substrate layer 331, the embodiment can prevent the first substrate layer 331 from being damaged.

Also, in the third embodiment, a first pad 333 may be disposed on an upper surface region of the image sensor 340 exposed through the first-second through hole 332-1.

At this time, the first pad 333 may overlap the image sensor 340 in the optical axis direction. Accordingly, the image sensor 340 in the third embodiment can be mounted on the first pad 333 using a flip chip bonding method. To this end, a bonding part (not shown) may be disposed between the first pad 333 and the terminal 341 of the image sensor 340. The bonding part may have a square shape (for example, a hexahedron shape), but is not limited thereto. For example, the bonding part may have a spherical shape. For example, a cross section of the bonding part may include a circular shape. For example, a cross section of the bonding part may include a partially or entirely rounded shape. For example, a cross-sectional shape of the bonding part may be flat on one side and curved on the other side opposite to the one side.

As such, the circuit board in the third embodiment includes a first substrate layer 331 and a second substrate layer 332. Additionally, the first substrate layer 331 includes a first-first through hole 331-1, and the second substrate layer 332 includes a first-second through hole 332-1. Additionally, a second plate portion 362, which is part of the reinforcing plate 360, may be disposed in the first-first through hole 331-1 of the first substrate layer 331. Additionally, an image sensor 340 may be disposed in the first-second through hole 332-1 of the second substrate layer 332. Accordingly, in the embodiment, the reinforcing plate 360 includes a first plate portion 361 and a second plate portion 362, thereby further improving heat dissipation of the image sensor 340. Furthermore, the embodiment may apply a flip chip bonding method rather than a wire bonding method, and accordingly, in the camera module, the first height (H1′) corresponding to the Flange Back Length (FBL) or the second height (H2′) corresponding to the Total Track Length (TTL) can be further reduced.

For example, in the third embodiment, the first height H1′ and the second height H2′ can be reduced by the height of the second plate portion 362 compared to the first embodiment.

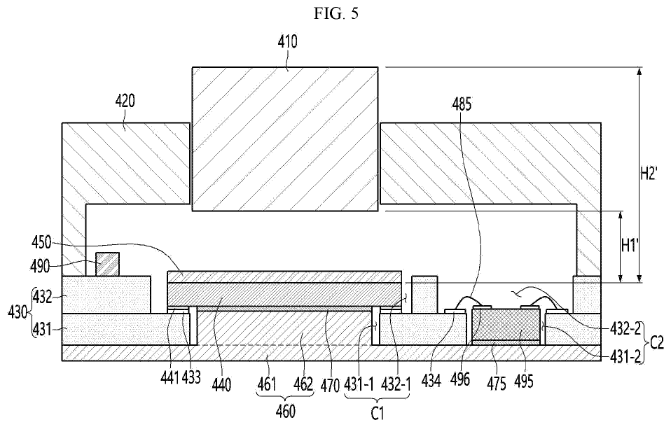

FIG. 5 is a cross-sectional view showing a camera module according to a fourth embodiment.

Referring to FIG. 5, the camera module of the fourth embodiment includes a lens module 410, a lens driving part 420, a circuit board 430, an image sensor 440, a filter 450, a reinforcing plate 460, a first adhesive member 470, a first connection member 480, a passive device 490, a second adhesive member 475, a driver device 495, and a second connection member 485.

At this time, an overall basic structure of each component of the camera module of the fourth embodiment is substantially the same as that of the camera module according to the third embodiment of FIG. 4, and therefore detailed description thereof will be omitted.

The camera module according to the fourth embodiment shown in FIG. 5 differs from the camera module according to the third embodiment shown in FIG. 4 in that the image sensor and the filter are configured as a package.

The circuit board 430 in the fourth embodiment includes the first substrate layer 431 and the second substrate layer 432. Additionally, the first substrate layer 431 may include a first-first through hole 431-1 that is a part of the cavity. And, the second substrate layer 432 may include a first-second through hole 432-1. At this time, the first-first through-hole 431-1 and the first-second through-hole 432-1 may at least partially overlap each other in the optical axis direction. For example, at least a portion of the first-second through-hole 432-1 may overlap with the first-first through-hole 431-1 in the optical axis direction. For example, a remaining portion of the first-second through-hole 432-1 may not overlap with the first-first through-hole 431-1 in the optical axis direction. For example, the width of the first-first through hole 431-1 may be different from the width of the first-second through hole 432-1. Preferably, the width of the first-first through hole 431-1 may be smaller than the width of the first-second through hole 432-1.

The filter 450 in the fourth embodiment may be disposed on the image sensor 440. For example, in an embodiment, the lower surface of the filter 450 may directly contact the upper surface of the image sensor 440. Accordingly, in the embodiment, a height between the image sensor 440 and the filter 450 can be minimized, and thus the height of the camera module can be dramatically reduced.

At this time, the filter 450 is attached to the image sensor 440, so that the filter 450 can be placed together with the image sensor 440 in the first-second through hole 432-1 of the second substrate layer 432. For example, the filter 450 may be accommodated in the first-second through hole 432-1 together with the image sensor 440. Preferably, a portion of the filter 450 is accommodated in the first-second through hole 432-1, and a remaining portion may protrude above the first-second through hole 432-1. Accordingly, in the embodiment, a height of the camera module can be reduced by a height corresponding to a separation space between the image sensor 440 and the filter 450 compared to the comparative example, and thus the camera module can be miniaturized.

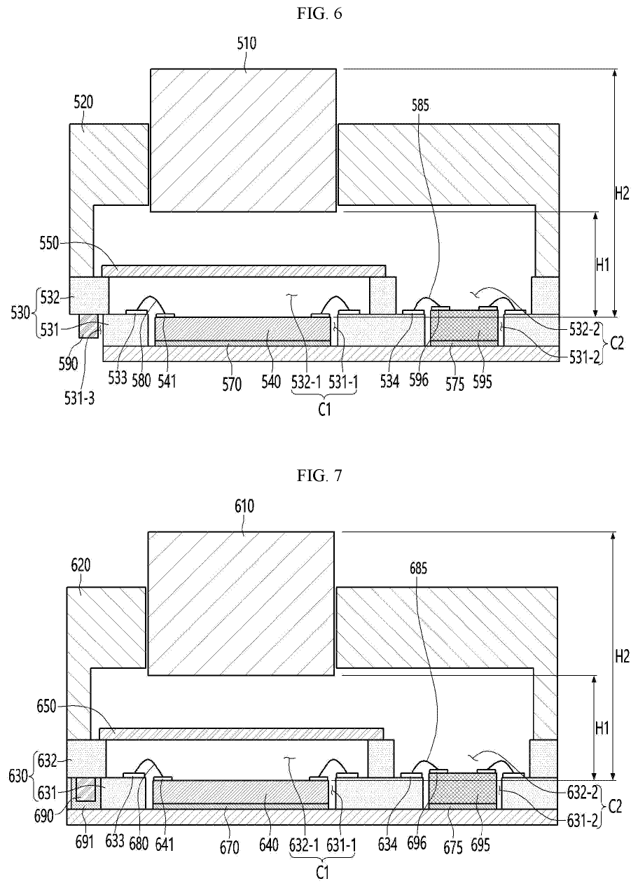

FIG. 6 is a cross-sectional view showing a camera module according to a fifth embodiment.

Referring to FIG. 6, the camera module of the fifth embodiment includes a lens module 510, a lens driving part 520, a circuit board 530, an image sensor 540, a filter 550, a reinforcing plate 560, a first adhesive member 570, a first connection member 580, a passive device 590, a second adhesive member 575, a driver device 595, and a second connection member 585.

At this time, an overall basic structure of each component of the camera module of the fifth embodiment is substantially the same as that of the camera module according to the second embodiment of FIG. 3, and therefore detailed description thereof will be omitted.

The first substrate layer 531 in the fifth embodiment may include a third through hole 531-3. At this time, the third through hole 531-3 of the first substrate layer 531 in the fifth embodiment may be formed to pass through the first substrate layer 531. For example, the third through-hole 531-3 may be formed to be spaced apart from the first-first through-hole 531-1 of the first substrate layer 531 in a direction perpendicular to the optical axis. Additionally, the third through hole 531-3 may expose at least a portion of the lower surface of the second substrate layer 532. At this time, although not shown in the drawing, a mounting pad (not shown) may be disposed on the lower surface of the second substrate layer 532 exposed through the third through hole 531-3. Additionally, a passive device 590 may be mounted on the mounting pad. At this time, when mounting the passive device 590, the embodiment allows at least a portion of the passive device 590 to be disposed in the third through hole 531-3 of the first substrate layer 531. Accordingly, in the embodiment, the height occupied by the passive device 590 can be minimized, and thus the height of the camera module can be further reduced.

Additionally, according to the camera module of the fifth embodiment, as the passive device 590 is disposed on the lower surface of the circuit board, the size in the direction perpendicular to the optical axis of the camera module can be minimized.

For example, according to FIGS. 2 to 4, the size of the circuit board in a direction perpendicular to the optical axis increased by the size corresponding to the arrangement space of the device. Differently, according to the fifth embodiment, the passive device may be placed on the lower surface of the circuit board, and accordingly, the size of the circuit board in a direction perpendicular to the optical axis can be reduced, and further miniaturization of the camera module is possible.

FIG. 7 is a cross-sectional view of a camera module according to a sixth embodiment.

Referring to FIG. 7, the camera module may include a lens module 610, a lens driving part 620, a circuit board 630, an image sensor 640, a filter 650, a reinforcing plate 660, a first adhesive member 670, a first connection member 680, a passive device 690, a second adhesive member 675, a driver device 695, and a second connection member 685.

At this time, in the fifth embodiment, the first substrate layer 531 includes a third through hole 531-3. The third through hole 531-3 exposes a portion of the lower surface of the second substrate layer 532. And, the passive device 590 is mounted on the lower surface of the second substrate layer 533 exposed through the third through hole 531-3. At this time, the passive device 590 in the fifth embodiment did not overlap with the reinforcing plate in the optical axis direction or in the vertical direction.

Unlike this, the first substrate layer 631 in the embodiment of FIG. 6 includes a third through hole, and the third through hole may overlap the reinforcing plate 660 along the optical axis direction or in the vertical direction.

Accordingly, the passive device 690 in the embodiment may be arranged to vertically overlap the reinforcing plate 660. However, the passive device 690 is mounted on the lower surface of the second substrate layer exposed through the third through hole. Accordingly, the passive device 690 cannot directly contact the reinforcing plate 660.

For this purpose, in the embodiment, a molding layer 691 is formed within the third through hole. The molding layer 691 is disposed to fill the third through hole. For example, the molding layer 691 may mold the passive device 690 disposed in the third through hole.

At this time, the molding layer 691 may contact the reinforcing plate 660. Through this, in the embodiment, heat generated in the passive device 690 can be transferred to the outside through the reinforcing plate 660 and the molding layer 691.

At this time, the molding layer 691 may have a low dielectric constant to increase heat dissipation characteristics. For example, the dielectric constant (Dk) of the molding layer 691 may be 0.2 to 10. For example, the dielectric constant (Dk) of the molding layer 691 may be 0.5 to 8. For example, the dielectric constant (Dk) of the molding layer 691 may be 0.8 to 5. Accordingly, in the embodiment, the molding layer 691 has a low dielectric constant to improve heat dissipation characteristics for heat generated from the passive device 690.

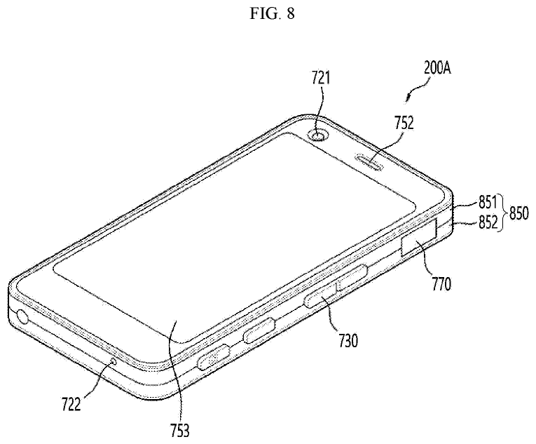

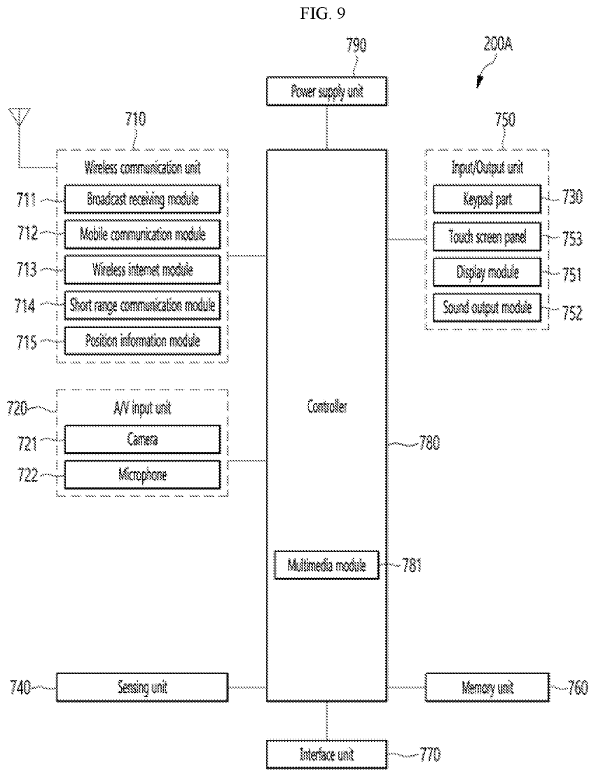

FIG. 8 is a perspective view of a portable terminal 200A according to an embodiment, and FIG. 9 is a block diagram of the portable terminal shown in FIG. 16.

FIGS. 8 and 9, the portable terminal (200A, hereinafter referred to as “terminal”) may include a body 850, a wireless communication unit 710, an A/V input unit 720, and a sensing unit 740, an input/output unit 750, a memory unit 760, an interface unit 770, a control unit 780, and a power supply unit 790.

The body 850 shown in FIG. 8 is in the form of a bar, but is not limited thereto, and there may be various structures such as a slide type, a folder type, a swing type, a swivel type, in which two or more sub-bodies are coupled to be movable relative to each other.

The body 850 may include a case (casing, housing, cover, etc.) forming an exterior. For example, the body 850 may be divided into a front case 851 and a rear case 852. Various electronic components of the terminal may be embedded in a space formed between the front case 851 and the rear case 852.

The wireless communication unit 710 may include one or more modules that enable wireless communication between the terminal 200A and the wireless communication system or between the terminal 200A and the network in which the terminal 200A is located. For example, the wireless communication unit 710 may include a broadcast reception module 711, a mobile communication module 712, a wireless internet module 713, a short-range communication module 714, and a location information module 715.

The A/V (Audio/Video) input unit 720 is for inputting an audio signal or a video signal, and may include a camera 721 and a microphone 722 and the like.

The camera 721 may include a camera module according to the embodiment shown in FIGS. 2 to 7.

The sensing unit may detect a current state of the terminal 200A, such as an opening/closing state of the terminal 200A, a position of the terminal 200A, a presence or absence of user contact, an orientation of the terminal 200A, acceleration/deceleration of the terminal 200A, etc. and generate a sensing signal for controlling the operation of the terminal 200A. For example, when the terminal 200A is in the form of a slide phone, it is possible to sense whether the slide phone is opened or closed. In addition, it is responsible for sensing functions related to whether the power supply unit 790 is supplied with power, whether the interface unit 770 is coupled to an external device, and the like.

The input/output unit 750 is for generating input or output related to sight, hearing, or touch. The input/output unit 750 may generate input data for operation control of the terminal 200A, and may also display information processed by the terminal 200A.

The input/output unit 750 may include a keypad unit 730, a display module 751, a sound output module 752, and a touch screen panel 753. The keypad unit 730 may generate input data in response to a keypad input.

The display module 751 may include a plurality of pixels whose color changes according to an electrical signal. For example, the display module 751 may include at least of a liquid crystal display, a thin film transistor-liquid crystal display, an organic light-emitting diode, a flexible display, three-dimensional display (3D display).

The sound output module 752 may output audio data received from the wireless communication unit 710 in a call signal reception, a call mode, a recording mode, a voice recognition mode, or a broadcast reception mode, or the like; or audio data stored in the memory unit 760.

The touch screen panel 753 may convert a change in capacitance generated due to a user's touch on a specific region of the touch screen into an electrical input signal.

The memory unit 760 may store a program for processing and control of the controller 780, and may temporarily store input/output data (eg, phone book, message, audio, still image, photo, video, etc.). For example, the memory unit 760 may store an image captured by the camera 721, for example, a photo or a moving picture.

The interface unit 770 serves as a passage for connecting with an external device connected to the terminal 200A. The interface unit 770 receives data from an external device, receives power and transmits it to each component inside the terminal 200A, or transmits data of the terminal 200A to an external device. For example, the interface unit 770 may include a wired/wireless headset port, an external charger port, a wired/wireless data port, a memory card port, a port for connecting a device having an identification module, and an audio I/O (Input/Output) port, video I/O (Input/Output) port, and an earphone port, and the like.

The controller (controller, 780) may control the overall operation of the terminal 200A. For example, the controller 780 may perform related control and processing for voice calls, data communications, video calls, and the like.

The controller 780 may include a multimedia module 781 for playing multimedia. The multimedia module 781 may be implemented within the controller 180 or may be implemented separately from the controller 780.

The controller 780 may perform a pattern recognition process capable of recognizing a handwriting input or a drawing input performed on the touch screen as characters and images, respectively.

The power supply unit 790 may receive external power or internal power under the control of the control unit 780 to supply power required for the operation of each component.

Although the embodiments of the present invention have been described with reference to the accompanying drawings, those skilled in the art to which the present invention pertains will be understood that the present invention may be implemented in other specific forms without modifying the technical spirit and essential features of the present invention. Therefore, it should be understood that the embodiments described above are illustrative in all aspects and not restrictive.

1. A camera module comprising:
a reinforcing plate;
a circuit board disposed on the reinforcing plate and having first and second through holes spaced apart from each other along a horizontal direction;
an image sensor disposed in the first through hole of the circuit board;
a driver device disposed in the second through hole of the circuit board,
wherein the image sensor and the driver device overlap each other along the horizontal direction.

2. The camera module of claim 1, wherein the driver device and the image sensor are non-overlapping with each other along a vertical direction.

3. The camera module of claim 2, comprising:
a first adhesive member disposed between the reinforcing plate and the image sensor; and
a second adhesive member disposed between the reinforcing plate and the driver device,
wherein the reinforcing plate includes:
a first region overlapping the circuit board in the vertical direction,
a second region overlapping the first through hole in the vertical direction;
a third region overlapping the second through hole in the vertical direction,
wherein an upper surface of the first region is in contact with the circuit board,
wherein an upper surface of the second region is in contact with the first adhesive member, and
wherein an upper surface of the third region is in contact with the second adhesive member.

4. The camera module of claim 3, wherein the circuit board includes first and second substrate layers stacked in a vertical direction,
wherein at least one of the first through hole and the second through hole includes:
a first part provided in the first substrate layer and a second part provided in the second substrate layer and overlapped with the first part in the vertical direction, and
wherein a horizontal width of the first part and a horizontal width of the second part are different from each other.

5. The camera module of claim 4, wherein the circuit board includes a first pad connected to the image sensor and a second pad connected to the driver device,
wherein the first through hole includes the first part and the second part,
wherein a horizontal width of the second part is greater than a horizontal width of the first part, and
wherein the first pad is disposed on an upper surface of the first substrate layer vertically overlapping with the second part of the first through hole.

6. The camera module of claim 5, further comprising:
a first connection member connecting a terminal of the image sensor and the first pad,
wherein the first connection member is disposed in the second part of the first through hole, and
wherein an uppermost end of the first connection member is located lower than an uppermost end of the second substrate layer.

7. The camera module of claim 5, wherein the second through hole includes the first part and the second part,
wherein a horizontal width of the second part is greater than a horizontal width of the first part, and
wherein the second pad is disposed on an upper surface of the first substrate layer vertically overlapping with the second part of the second through hole.

8. The camera module of claim 7, comprising:
a second connection member connecting a terminal of the driver device and the second pad, and
wherein the second connection member is disposed in the second part of the second through hole, and
wherein an uppermost end of the second connection member is located lower than an uppermost end of the second substrate layer.

9. The camera module of claim 5, wherein the image sensor includes an overlapping region disposed in the second part of the second through hole of the first cavity and overlapping the first pad in the vertical direction.

10. The camera module of claim 9, wherein an upper surface of the reinforcing plate has a step, and
wherein at least one of the first through hole and the second through hole overlaps the step in the vertical direction.

11. The camera module of claim 10, wherein an upper surface of the second region of the reinforcing plate is located higher than an upper surface of the third region of the reinforcing plate.

12. The camera module of claim 10, wherein the reinforcing plate includes:
a first plate portion; and
a second plate portion partially disposed on the first plate portion,
wherein the second plate portion is provided in at least one of the first and second through holes and overlaps the circuit board in the horizontal direction.

13. The camera module of claim 12, wherein the second plate portion is provided in the first through hole, and
wherein the image sensor is disposed on the second plate portion.

14. The camera module of claim 13, wherein the driver device is disposed on the first plate portion.

15. The camera module of claim 3, comprising:
a filter disposed on the circuit board,
wherein a lower surface of the filter is in direct contact with an upper surface of the second substrate layer of the circuit board.

16. The camera module of claim 10, comprising:
a filter disposed on the image sensor,
wherein the filter is attached to the image sensor, and
wherein at least a portion of the filter is located within the second part of the first through hole.

17. The camera module of claim 3, comprising a passive device disposed under the circuit board,
wherein the first substrate layer includes a third through hole spaced apart from the first and second through holes in the horizontal direction and overlapping the second substrate layer in the vertical direction, and
wherein the passive device is disposed in the third through hole.

18. The camera module of claim 17, comprising:
a molding layer provided in the third through hole and molding the passive device, and
wherein the molding layer is in contact with the reinforcing plate.

19. An optical device comprising:
a camera module, and
a display unit configured to output images captured by the camera module,
wherein the camera module comprises:
a reinforcing plate;
a circuit board disposed on the reinforcing plate and having first and second through holes spaced apart from each other along a horizontal direction;
an image sensor disposed in the first through hole of the circuit board;
a driver device disposed in the second through hole of the circuit board;
a first adhesive member disposed between the reinforcing plate and the image sensor; and
a second adhesive member disposed between the reinforcing plate and the driver device,
wherein the image sensor and the driver device overlap each other along the horizontal direction and do not overlap each other along the vertical direction,
wherein the reinforcing plate includes a first region overlapping in the vertical direction with the circuit board, a second region overlapping in the vertical direction with the first through hole, and a third region overlapping in the vertical direction with the second through hole,
wherein an upper surface of the first region is in contact with the circuit board,
wherein an upper surface of the second region is in contact with the first adhesive member, and
wherein an upper surface of the third region is in contact with the second adhesive member.

20. The optical device of claim 19, wherein the reinforcing plate includes:
a first plate portion; and
a second plate portion partially disposed on the first plate portion,
wherein the second plate portion is located in the first through hole,
wherein the image sensor is disposed on the second plate portion, and
wherein the driver device is disposed on the first plate portion.
